(19) United States
(12) Patent Application Publication
(10) Pub. No.: US 2020/0032394 A1
(43) Pub. Date: Jan. 30, 2020

(54) FILM DEPOSITION APPARATUS

(71) Applicant: TOSHIBA MITSUBISHI-ELECTRIC INDUSTRIAL SYSTEM CORPORATION, Chuo-ku (JP)

(72) Inventors: Hiroyuki ORITA, Tokyo (JP); Takahiro HIRAMATSU, Tokyo (JP)

(73) Assignee: TOSHIBA MITSUBISHI-ELECTRIC INDUSTRIAL SYSTEM CORPORATION, Chuo-ku (JP)

(21) Appl. No.: 16/081,993

(22) PCT Filed: Apr. 26, 2016
(86) PCT No.: PCT/JP2016/063018

§ 371 Date: Sep. 4, 2018

(51) Int. Cl. C23C 16/458; C23C 16/46; H01L 21/677; H01L 21/683

(52) U.S. Cl. CPC C23C 16/4583; H01L 21/6838; H01L 21/6776; C23C 16/46

(57) ABSTRACT

In the present invention, a suction gripper which performs an substrate introducing operation for a substrate loading stage and a suction gripper which performs a substrate retrieving operation from the substrate loading stage have heating mechanisms. Consequently, the heating mechanisms can perform first and second preheating treatments for heating a substrate even in a state where the suction grippers grip the substrate.

### TECHNICAL FIELD

The present invention relates to a film deposition apparatus which is used for a solar cell, an electronic apparatus or the like and deposits a thin film on a substrate.

### BACKGROUND ART

Conventionally, when a thin film is deposited by a film deposition apparatus such as a thin film manufacturing apparatus requiring thermal energy, it is necessary to perform a heating treatment for a substrate. In this case, on the other hand, high treatment capability (short tact time) is required, so that the heat treatment for the substrate is desirably performed in as short a time as possible. When a normal temperature substrate is transferred to a preheated substrate loading stage, the heating treatment for the substrate can be executed in a relatively short time on the substrate loading stage. However, in that case, a temperature gradient occurs between the upper and lower surfaces of the substrate, which causes a problem that the substrate is warped or broken.

Therefore, in the conventional film deposition apparatus, a preheating chamber is separately provided in front of a thin film forming treatment chamber, to previously heat the substrate, and the substrate is then transported to the thin film forming treatment chamber, to shorten a heating time during a thin film deposition treatment, thereby achieving high treatment capacity (throughput) of a film deposition treatment. Examples of the film deposition apparatus provided with the preheating chamber include a sputtering apparatus disclosed in Patent Document 1 and a CVD apparatus disclosed in Patent Document 2.

The sputtering apparatus disclosed in Patent Document 1 includes two heating chambers as the preheating chamber in front of a film deposition treatment portion. The CVD apparatus disclosed in Patent Document 2 causes a loop-shaped belt conveyor to transport a substrate, and includes a substrate preheating zone and a CVD heating zone which function as the preheating chamber in the path.

A semiconductor manufacturing apparatus which includes a plurality of heater blocks including a heating mechanism and loading a substrate and circulates the heater blocks is disclosed in, for example, Patent Document 3. The semiconductor manufacturing apparatus circulates a large number of heater blocks, to allow a heating treatment to be relatively slowly performed while high treatment capability is measured.

### PRIOR ART DOCUMENTS

### Patent Documents

Patent Document 1: Japanese Patent Application Laid-Open No. 3-191063 (1991)
Patent Document 2: Japanese Patent Application Laid-Open No. 2007-92152
Patent Document 3: Japanese Patent Application Laid-Open No. 63-166217 (1988)

### SUMMARY

### Problem to be Solved by the Invention

However, in the apparatuses disclosed in Patent Documents 1 and 2, the preheating chamber (heating chamber (Patent Document 1) and substrate preheating zone (Patent Document 2)) are separately provided, which causes increased manufacturing cost, resulting in increased footprint (area occupied by the manufacturing apparatus).

The semiconductor manufacturing apparatus disclosed in Patent Document 3 makes it necessary to include a large number of (8 or more in FIG. 1) heater blocks in order to continuously transport the heater blocks to below a gas supply nozzle. Furthermore, the semiconductor manufacturing apparatus causes complicated connection of power supply wires and vacuum pipes for a large number of heater blocks, which causes increased footprint and cost of the apparatus. When the number of the heater blocks is increased, there is a concern that a film deposition treatment time becomes unnecessarily long, which causes lowered treatment capability during film deposition.

In addition, the semiconductor manufacturing apparatus disclosed in Patent Document 3 performs the heating treatment in a state where the substrate (wafer) is simply placed on the heater blocks, so that the problem that the substrate is warped or cracked as soon as a temperature gradient occurs in the substrate is not solved.

The present invention solves the above-mentioned problems, and it is an object of the present invention to provide a film deposition apparatus which effectively suppresses a phenomenon in which warpage or cracking occurs in a film deposition substrate while minimizing the cost of the apparatus.

### Means to Solve the Problem

A film deposition apparatus according to the present invention includes: a substrate placing portion which places a substrate and includes a main heating mechanism for heating the placed substrate at a main heating temperature; a first gripper which executes a substrate introducing operation for gripping a film deposition substrate placed on a substrate introducing portion, moving the substrate in a state where the substrate is gripped, and placing the substrate on the substrate placing portion; a film deposition treatment executing portion which executes a film deposition treatment for depositing a thin film for the substrate placed on the substrate placing portion in a film deposition treatment region; a substrate placing portion transferring device which executes a transporting operation for moving the substrate placing portion to cause the substrate placing portion to pass through the film deposition treatment region; and a second gripper which executes a substrate retrieving operation for gripping the substrate located on the substrate placing portion and having the thin film deposited by executing the film deposition treatment, moving the substrate in a state where the substrate is gripped, and placing the substrate on a substrate retrieving portion, wherein at least one of the first and second grippers includes preheating mechanisms for heating the gripped substrate at a preheating temperature in the state where the substrate is gripped.

### Effects of the Invention

The substrate placing portion of the film deposition apparatus in the present invention includes the main heating mechanism for heating the substrate at the main heating temperature, so that the placed substrate can be heated at the main heating temperature. In addition, at least one of the first and second grippers includes the preheating mechanism for heating the gripped substrate at the preheating temperature in the state where the substrate is gripped, so that the substrate can be heated even during at least one of the substrate introducing operation and the substrate retrieving operation.

This makes it possible to execute the heating treatment for the substrate (heating treatment at the preheating temperature and the main heating temperature) over a long period of time, so that the necessity of rapidly performing the heating treatment is eliminated. As a result, the occurrence of warpage or cracking in the substrate can be effectively suppressed by performing the heating treatment in a short period of time.

As the main additional constituent part of the film deposition apparatus of the present invention, the heating mechanism is merely provided in at least one of the first and second grippers required for the substrate introducing operation and the substrate retrieving operation, so that the cost of the apparatus can be minimized.

The objects, features, aspects, and advantages of the present invention will become more apparent from the following detailed description and the accompanying drawings.

### BRIEF DESCRIPTION OF DRAWINGS

FIG. 1 is an illustration diagram showing a schematic configuration of a film deposition apparatus according to an embodiment of the present invention.

FIG. 2 is a cross-sectional view schematically showing a substrate transferring mechanism and its periphery.

FIG. 3 is an illustration diagram (part 1) showing a transporting operation of two substrate loading stages in the film deposition apparatus of the present embodiment.

FIG. 4 is an illustration diagram (part 2) showing a transporting operation of two substrate loading stages in the film deposition apparatus of the present embodiment.

FIG. 5 is an illustration diagram (part 3) showing a transporting operation of two substrate loading stages in the film deposition apparatus of the present embodiment.

FIG. 6 is an illustration diagram (part 4) showing a transporting operation of two substrate loading stages in the film deposition apparatus of the present embodiment.

FIG. 7 is an illustration diagram (part 5) showing a transporting operation of two substrate loading stages in the film deposition apparatus of the present embodiment.

FIG. 8 is an illustration diagram (part 6) showing a transporting operation of two substrate loading stages in the film deposition apparatus of the present embodiment.

FIG. 9 is an illustration diagram (part 7) showing a transporting operation of two substrate loading stages in the film deposition apparatus of the present embodiment.

FIG. 10 is an illustration diagram (part 8) showing a transporting operation of two substrate loading stages in the film deposition apparatus of the present embodiment.

FIG. 11 is an illustration diagram (part 9) showing a transporting operation of two substrate loading stages in the film deposition apparatus of the present embodiment.

FIG. 12 is an illustration diagram (part 10) showing a transporting operation of two substrate loading stages in the film deposition apparatus of the present embodiment.

FIG. 13 is an illustration diagram (part 11) showing a transporting operation of two substrate loading stages in the film deposition apparatus of the present embodiment.

FIG. 14 is an illustration diagram (part 12) showing a transporting operation of two substrate loading stages in the film deposition apparatus of the present embodiment.

FIG. 15 is an illustration diagram (part 13) showing a transporting operation of two substrate loading stages in the film deposition apparatus of the present embodiment.

FIG. 16 is an illustration diagram (part 14) showing a transporting operation of two substrate loading stages in the film deposition apparatus of the present embodiment.

FIG. 17 is an illustration diagram (part 15) showing a transporting operation of two substrate loading stages in the film deposition apparatus of the present embodiment.

FIG. 18 is an illustration diagram showing a substrate introducing operation of a suction gripper of the present embodiment.

FIG. 19 is an illustration diagram schematically showing a configuration of a conventional film deposition apparatus.

FIG. 20 is an illustration diagram showing a conventional substrate introducing operation in the conventional film deposition apparatus.

### DESCRIPTION OF EMBODIMENTS

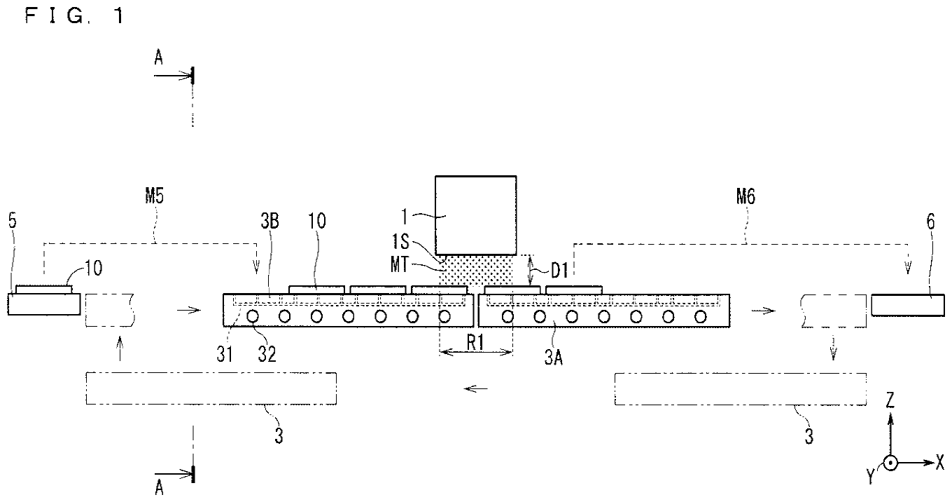

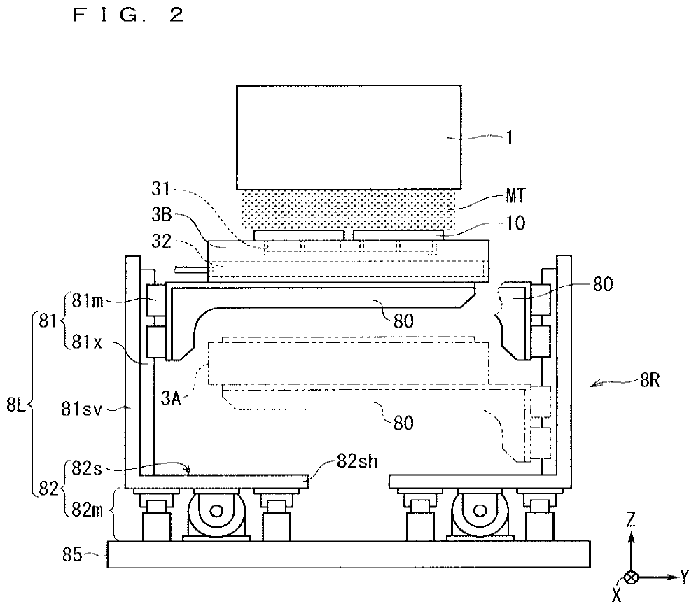

FIG. 1 is an illustration diagram showing a schematic configuration of a film deposition apparatus according to an embodiment of the present invention. As shown in FIG. 1, a plurality of substrates 10 are placed on an upper surface of each of substrate loading stages 3A and 3B (first and second substrate placing portions). FIG. 1, and FIGS. 2 to 17 and 19 to be shown below show an XYZ orthogonal coordinate system.

Each of the substrate loading stages 3A and 3B includes suction mechanisms 31 according to vacuum suction. The suction mechanisms 31 allow the entire lower surface of each of the plurality of placed substrates 10 to be suctioned onto the upper surface of each of the substrate loading stages 3A and 3B. Furthermore, each of the substrate loading stages 3A and 3B includes heating mechanisms 32 below the suction mechanism 31. The heating mechanisms 32 can execute a heating treatment for the plurality of substrates 10 placed on the upper surface.

Hereinafter, the substrate loading stages 3A and 3B are sometimes collectively referred to as a “substrate loading stage 3”.

A thin film forming nozzle 1 (mist injecting portion) functioning as a film deposition treatment executing portion injects a raw material mist MT downward from an injecting port provided on an injecting surface 1S, thereby executing a film deposition treatment for depositing a thin film on the substrate 10 placed on the upper surface of the substrate loading stage 3 in an injection region R1 (film deposition treatment region). In this case, a mist injecting distance D1, which is a distance between the injecting surface 1S and the substrate 10, is set to 1 mm or more and 30 mm or less. The periphery of the injection region R1 is generally covered with a chamber (not shown) or the like.

A main heating treatment provided by the heating mechanism 32 (main heating mechanism) of the substrate loading stage 3 is executed during the film deposition treatment and before and after the film deposition treatment. In the present embodiment, a heating temperature during the heating treatment provided by the heating mechanism 32 is about 400° C.

The raw material mist MT is a mist obtained by misting a raw material solution, and can be injected into the air.

The substrate loading stages 3A and 3B are transported by a substrate transferring mechanism 8 (substrate placing portion transferring device) to be described later. The substrate transferring mechanism 8 executes a transporting operation for moving the substrate loading stages 3A and 3B to cause the substrate loading stages 3A and 3B to sequentially pass through the injection region R1 at a speed V0 (moving speed during film deposition).

The transporting operation includes a circulating transporting treatment for circulating and arranging one of the substrate loading stages 3A and 3B (for example, the substrate loading stage 3A) at a circulating speed behind the other substrate loading stage (for example, substrate loading stage 3B). The substrate loading stage 3A is a substrate placing portion causing all the placed substrates 10 to pass through the injection region R1.

On a substrate introducing portion 5 provided on the upstream side of the thin film forming nozzle 1, the substrate 10 before the film deposition treatment is placed. The substrate 10 on the substrate introducing portion 5 is arranged on the upper surface of the substrate loading stage 3 by a substrate introducing operation M5 provided by a suction gripper 4A to be described later.

A substrate retrieving portion 6 is provided on the downstream side of the thin film forming nozzle 1. The substrate 10 after the film deposition treatment on the substrate loading stage 3 is arranged on the substrate retrieving portion 6 by a substrate retrieving operation M6 provided by a suction gripper 4B (second gripper) to be described later.

Herein, a transport direction (+X direction) side when the substrate loading stages 3A and 3B pass through the injection region R1 with respect to the thin film forming nozzle 1 is defined as a downstream side, and a counter transport direction (−X direction) side which is a direction opposite to the transport direction is defined as an upstream side.

FIG. 2 is a cross-sectional view schematically showing the substrate transferring mechanism 8 and its periphery in the A-A cross-section of FIG. 1. The substrate transferring mechanism 8 provided on a support plate 85 is constituted by the combination of a transferring mechanism 8L and a transferring mechanism SR which are operated independently of each other. The transferring mechanism SR is provided for transporting the substrate loading stage 3A. The transferring mechanism 8L is provided for transporting the substrate loading stage 3B. The support plate 85 has a planar shape including at least a transporting plane area defined by an XY plane requiring a transporting operation provided by the substrate introducing portion 5.

The transferring mechanism 8L includes an elevating mechanism 81 and a traverse mechanism 82. The traverse mechanism 82 includes a supporting member 82s having an L-shaped cross section and a moving mechanism 82m provided on the lower surface of a horizontal plate 82sh (L-shaped cross bar portion) of the supporting member 82s. The moving mechanism 82m includes, for example, a direct acting guide and a power transmission screw, and is provided so as to be movable along the X direction on the support plate 85 by the driving force of a motor.

The elevating mechanism 81 includes an elevating member 81m and an elevating shalt 81x. The elevating shaft 81x is erected and fixedly attached to a vertical plate 82sv (L-shaped vertical bar portion) of the supporting member 82s. The elevating member 81m is attached to the elevating shaft 81x so as to be freely elevated. A stage fixing member 80 is provided in connection with the elevating member 81m, and the lower surface of the substrate loading stage 3B is fixed on the upper surface of the stage fixing member 80.

The elevating operation of the elevating member 81m is considered to be, for example, an operation in which the rotational driving force of a rotational driving portion (not shown) is transmitted as vertical movement to a transmission mechanism such as a chain (not shown) which is provided in the elevating shaft 81x and is connected to the elevating member 81m. As a result, the elevating operation of the elevating member 81m can be achieved by the vertical movement of the above-described transmission mechanism.

Therefore, the transferring mechanism 8L can move the substrate loading stage 3B along the transport direction (+X direction) or move the substrate loading stage 3B along the counter transport direction (−X direction), according to a traverse operation along the X direction (+X direction or −X direction) of the moving mechanism 82m.

Furthermore, the transferring mechanism 8L can raise and lower the substrate loading stage 3B according to the elevating operation along the Z direction (+Z direction or −Z direction) of the elevating member 81m.

The transferring mechanism 8R is provided symmetrically with the transferring mechanism 8L with respect to a ZX plane in FIG. 2, and has a structure equivalent to that of the transferring mechanism 8L. Therefore, as with the transferring mechanism 8L, the transferring mechanism SR can move the substrate loading stage 3A along the transport direction and the counter transport direction according to the traverse operation of the traverse mechanism 82, and raise and lower the substrate loading stage 3A according to the elevating operation of the elevating mechanism 81. The positions of the substrate loading stages 3A and 3B in a Y direction are not changed according to the traverse operations and elevating operations of the transferring mechanisms 8L and 8R described above.

Thus, in the transferring mechanism 8L and the transferring mechanism SR, the vertical plate 82sv of the supporting member 82s and the elevating shaft 81x are formed at different positions in the Y direction. However, in both the transferring mechanism 8L and the transferring mechanism 8R, a cantilever support structure supports the substrate loading stage 3B and the substrate loading stage 3A. Therefore, by suitably combining the above-described traverse operation and elevating operation, transporting operations (including a circulating transporting treatment) can be executed independently of each other without causing interference between the substrate loading stages 3A and 3B.

In the example shown in FIG. 2, two substrates 10 can be placed along the Y direction on the substrate loading stage 3.

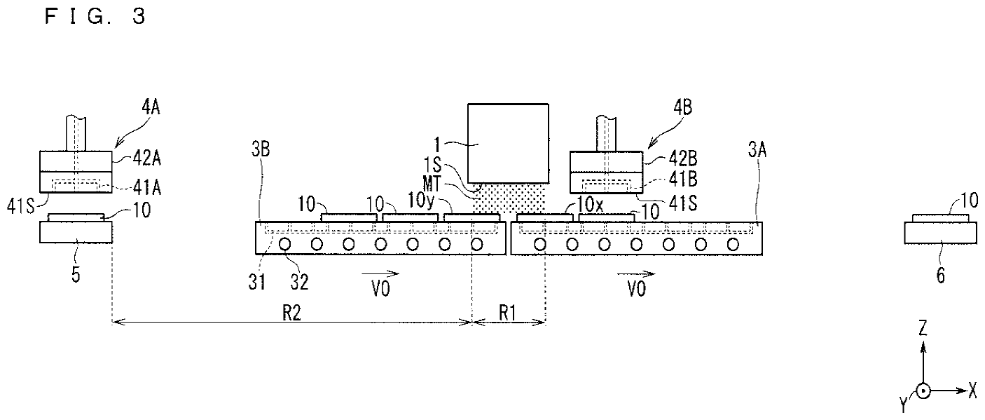

FIGS. 3 to 17 are illustration diagrams showing the transporting operations of the substrate loading stages 3A and 3B provided by the film deposition apparatus of the present embodiment. The transporting operation is performed by the substrate transferring mechanism 8 (transferring mechanism 8L+transferring mechanism 8R) shown in FIG. 2.

As shown in FIG. 3, by the traverse operations of the transferring mechanisms 8R and 8L, both the substrate loading stages 3A and 3B are transported in the transport direction (+X direction) at a speed V0. The raw material mist MT is injected onto the substrates 10 on the upper surfaces of the substrate loading stages 3A and 3B in the injection region R1, to execute a film deposition treatment for depositing a thin film on the upper surface of the substrate 10. In FIG. 3 and FIGS. 4 to 17 to be shown later, a region located on a further upstream side with respect to the injection region R1 is defined as a film depositing preparation region R2.

In the state shown in FIG. 3, both a rearmost substrate 10x on the substrate loading stage 3A and a frontmost substrate 10y on the substrate loading stage 3B are present in the injection region R1. On the upper surface of the substrate loading stage 3B, the substrate 10 located on the upstream side with respect to the substrate 10y is present in the film depositing preparation region R2, and is in a state before the film deposition treatment.

However, the substrate loading stage 3B includes the heating mechanism 32, so that a heating treatment can be executed even under a condition that the substrate 10 is present in the film depositing preparation region R2. At that time, by the suction mechanism 31, the entire lower surface of the substrate 10 is suctioned onto the upper surface of the substrate loading stage 3B, so that the substrate 10 is not warped or cracked even if a slight temperature gradient occurs in the substrate 10 by the heating treatment.

The substrate 10 before the film deposition treatment placed on the substrate introducing portion 5 is appropriately arranged on the upper surface of the substrate loading stage 3B (present in the film depositing preparation region R2) by the substrate introducing operation M5 provided by the suction gripper 4A (first gripper). The substrate 10 after the film deposition treatment which has passed through the injection region R1 on the substrate loading stage 3A is arranged on the substrate retrieving portion 6 by the substrate retrieving operation M6 provided by the suction gripper 4B.

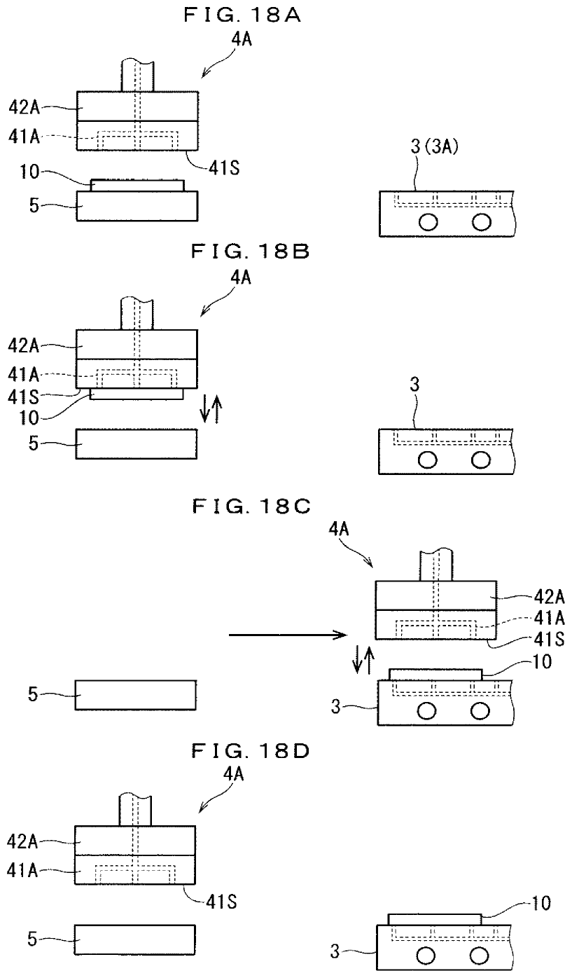

FIG. 18 is an illustration diagram showing the substrate introducing operation M5 of the suction gripper 4A in detail. Hereinafter, with reference to FIG. 18, the substrate introducing operation M5 will be described in detail.

First, as shown in FIGS. 18(a) and 18(b), the suction gripper 4A (first gripper) approaches above the substrate 10 placed on the substrate introducing portion 5. Then, a suction mechanism 41A suctions the upper surface of the substrate 10 to a gripping surface 41S so as to grip the substrate 10.

In a state where the substrate 10 is gripped, the suction gripper 4A is moved to above a substrate unloaded region, on which the substrate 10 is not placed, on the upper surface of the substrate loading stage 3 (above by a movement distance during release satisfying a movement distance condition to be described later).

As shown in FIG. 18(c), in the above state, a substrate releasing treatment for releasing a gripping state on the gripping surface 41S of the substrate 10 by the suction mechanism 41A of the suction gripper 4A is executed, to arrange the substrate 10 on the substrate unloaded region of the substrate loading stage 3. The above operation is the substrate introducing operation M5.

After the substrate introducing operation M5 is executed, as shown in FIG. 18(d), the suction gripper 4A moves to above the substrate introducing portion 5. The suction mechanism 41A suctions the substrate 10 according to vacuum suction, and the substrate releasing treatment is performed by blowing releasing gas from the suction mechanism 41A onto the upper surface of the substrate 10.

Next, the substrate retrieving operation M6 will be described in detail. First, the suction gripper 4B (second gripper) is moved to above the substrate 10 after the film deposition treatment which has passed through the injection region R1. In this state, a suction mechanism 41B suctions the upper surface of the substrate 10 on the substrate loading stage 3 to the gripping surface 41S (formed in the same manner as the gripping surface 41S of the suction gripper 4A shown in FIG. 18) so as to grip the substrate 10. In a state where the substrate 10 is gripped, the suction gripper 4B is moved to above the substrate unloaded region of the substrate retrieving portion 6 where the substrate is not placed (the position where the suction mechanism 41B can suction the substrate 10). In this state, the substrate releasing treatment for releasing the gripping state of the substrate 10 on the gripping surface 415 by the suction mechanism 41B of the suction gripper 4B is executed, to arrange the substrate 10 on the substrate unloaded region of the substrate retrieving portion 6. The above operation is the substrate retrieving operation M6. The suction mechanism 41B suctions the substrate 10 according to vacuum suction, and the substrate releasing treatment is performed by blowing releasing gas from the suction mechanism 41B onto the upper surface of the substrate.

The suction grippers 4A and 4B further include heating mechanisms 42A and 42B (first and second preheating mechanisms) above the suction mechanisms 41A and 41B, respectively. Therefore, in the substrate introducing operation M5 and the substrate retrieving operation M6, the heating mechanisms 42A and 42B can perform the first and second preheating treatments for heating the substrate 10 also in a state where the substrate 10 is gripped by the suction grippers 4A and 4B.

In the present embodiment, the heating mechanism 42A executes the first preheating treatment at a introducing gripping temperature of about 180° C. when the suction gripper 4A executes the substrate introducing operation M5. On the other hand, the heating mechanism 42B executes the second preheating treatment at a retrieving gripping temperature of about 240° C. when the suction gripper 4B executes the substrate retrieving operation M6.

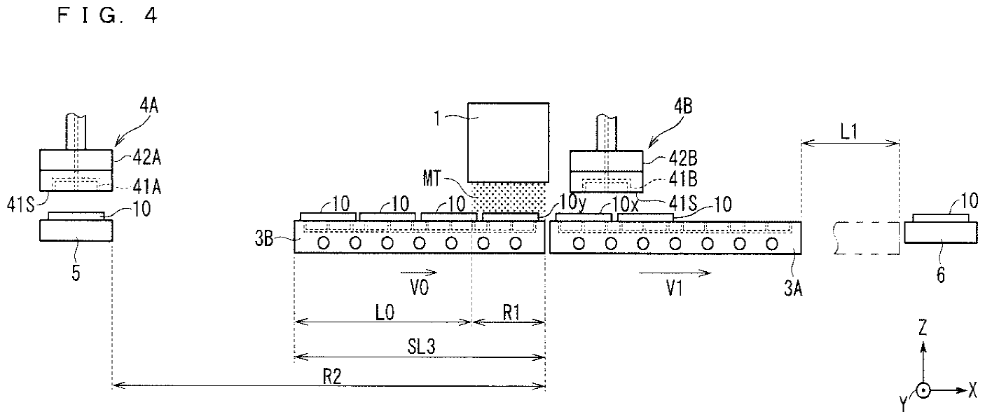

Thereafter, as shown in FIG. 4, when the rearmost substrate 10x on the upper surface of the substrate loading stage 3A passes through the injection region R1, all the substrates 10 placed on the upper surface of the substrate loading stage 3A pass through the injection region R1.

The circulating transporting treatment for the substrate loading stage 3A in this state is executed at speeds V1 to V5 (circulating speeds). First, the transferring mechanism 8R raises a transport speed according to the traverse operation from the speed V0 to the speed V1 (>V0). At this time, all the substrates 10 on the upper surface of the substrate loading stage 3A are moved onto the substrate retrieving portion 6 by the substrate retrieving operation M6 provided by the suction gripper 4B.

On the other hand, the substrate loading stage 3B maintains the transporting speed of the speed V0 according to the traverse operation of the transferring mechanism 8L.

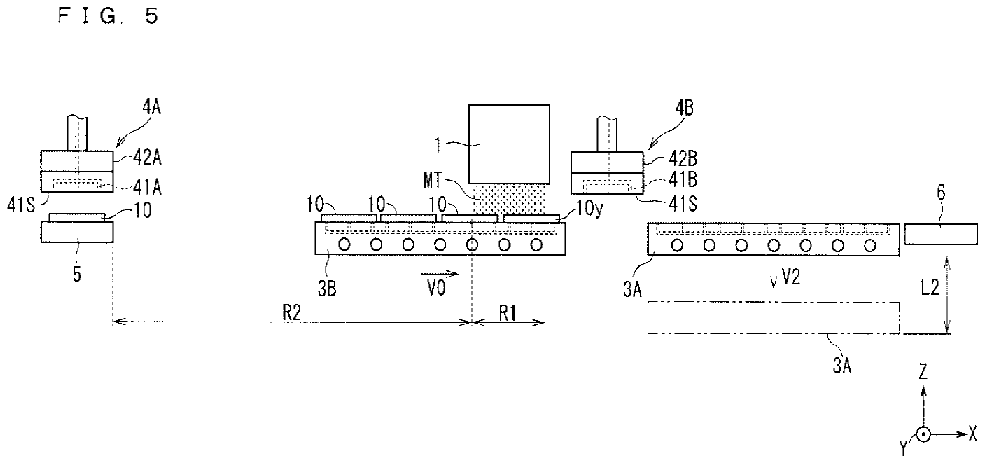

Then, as shown in FIG. 5, after all the substrates 10 on the upper surface of the substrate loading stage 3A are retrieved, the transferring mechanism 8R switches from the traverse operation to the elevating operation, and lowers the substrate loading stage 3A at the speed V2 (>V0). On the other hand, the substrate loading stage 3B on which the substrate 10 is present in the injection region R1 is transported along the transport direction at the speed V0 by the traverse operation of the transferring mechanism SL.

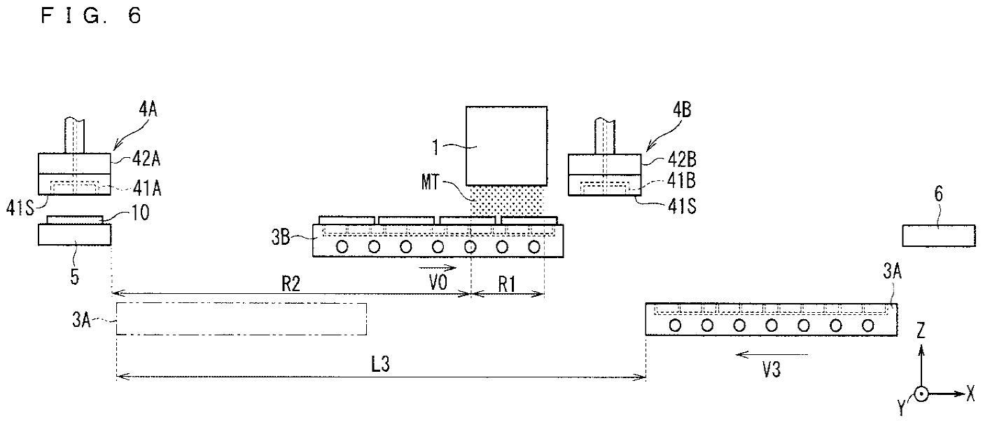

Thereafter, as shown in FIG. 6, by lowering the substrate loading stage 3A, a difference in height is provided between the substrate loading stages 3A and 3B such that the substrate loading stages 3A and 3B do not interfere with each other in the Z direction. The transferring mechanism SR then switches from the elevating operation to the traverse operation.

The substrate loading stage 3A is horizontally moved along the counter transport direction (−X direction) at the speed V3 (>V0) by the traverse operation of the transferring mechanism 8R. On the other hand, the substrate loading stage 3B on which the substrate 10 is present in the injection region R1 is transported at the speed V0 along the transport direction.

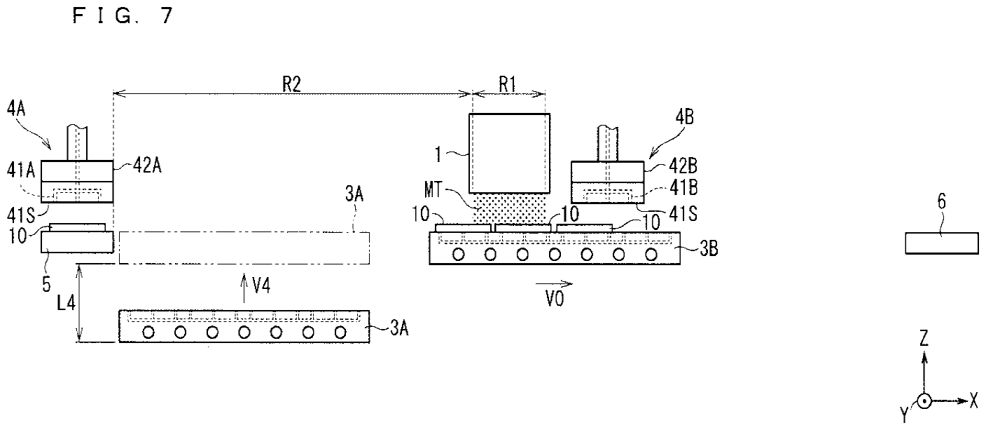

Thereafter, as shown in FIG. 7, the substrate loading stage 3A is horizontally moved to the upstream side which does not interfere with the substrate loading stage 3B in the X direction, and the transferring mechanism 8R then switches from the traverse operation to the elevating operation.

The substrate loading stage 3A is raised at the speed V4 (>V0) by the elevating operation of the transferring mechanism 8R. On the other hand, the substrate loading stage 3B on which the substrate 10 is present in the injection region R1 is transported along the transport direction at the speed V0.

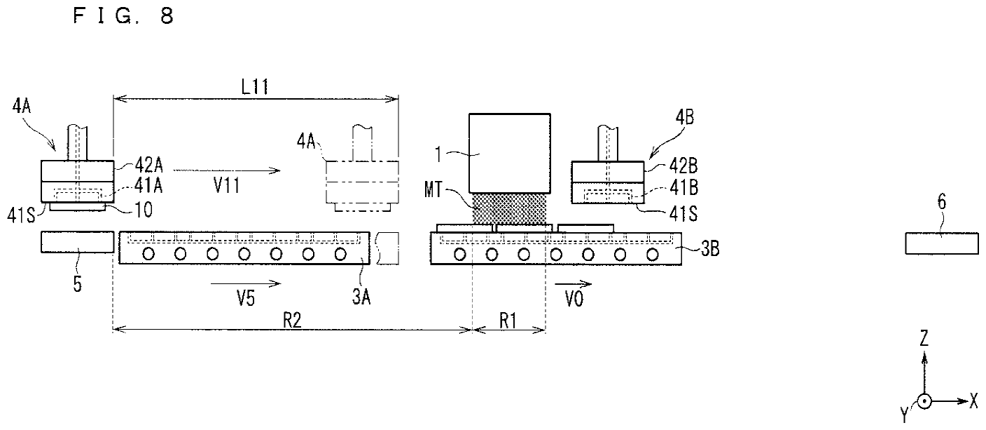

Next, as shown in FIG. 8, the substrate loading stage 3A reaches the same height as that of the substrate loading stage 3B, and the transferring mechanism 8R then switches from the elevating operation to the traverse operation.

The substrate loading stage 3A is transported at the speed V5 (>V0) along the transport direction by the traverse movement of the transferring mechanism 8R.

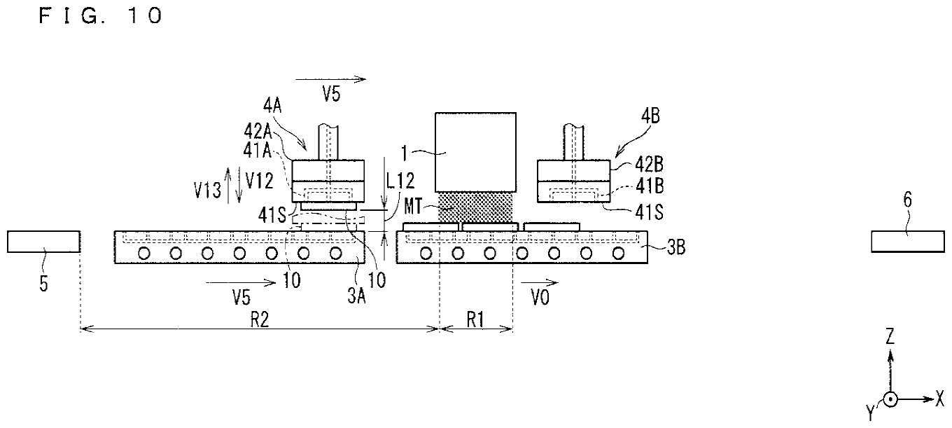

In parallel, as shown in FIG. 8, the substrate introducing operation M5 provided by the suction gripper 4A is executed. Specifically, the suction gripper 4A grips the substrate 10 before the film deposition treatment from the substrate introducing portion 5. The suction gripper 4A horizontally moves along the transport direction by a distance L11 at a speed V11 (>V5) while maintaining a difference in height (distance L12 (see FIG. 10)) where the gripped substrate 10 does not interfere with the substrate loading stage 3A.

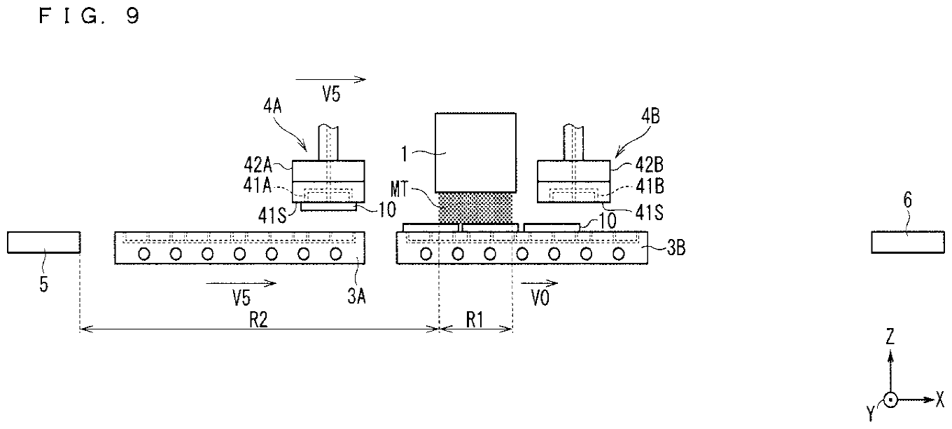

Thereafter, as shown in FIG. 9, when the suction gripper 4A reaches above the front end region of the substrate loading stage 3A in the transport direction, the speed is lowered from the speed V11 to the speed V5, and the suction gripper 4A horizontally moves along the transport direction at the same speed as that of the substrate loading stage 3A.

As shown in FIG. 10, the suction gripper 4A performs the lowering operation of a speed V12 together with the horizontal movement of the speed V5 in the transport direction. When the movement distance during release which is a distance (vertical distance along the Z direction) between the lower surface of the gripped substrate 10 and the upper surface of the substrate loading stage 3A satisfies a movement distance condition {more than 0 mm and 10 mm or less} which can accurately execute the substrate releasing treatment for the substrate 10 provided by the suction gripper 4A, the lowering operation is stopped, and the substrate releasing treatment is executed. Thereafter, the raising operation is performed at a speed V13, and the distance is returned to a sufficient difference in height (distance L12) where the substrate 10 does not interfere with the substrate loading stage 3A. Therefore, the movement distance during release when the movement distance condition is satisfied and the lowering operation of the suction gripper 4A is stopped becomes a movement distance during release just before the execution of the substrate releasing treatment.

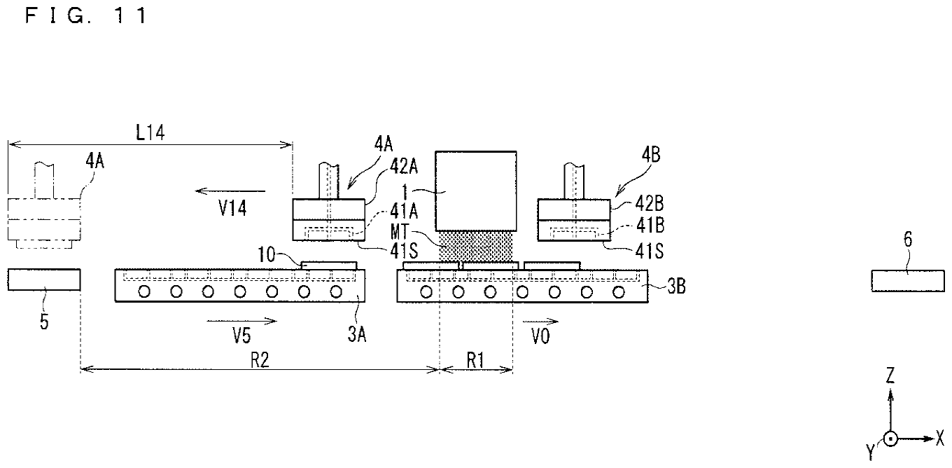

As shown in FIG. 11, the suction gripper 4A horizontally moves in the counter transport direction by a distance L14 at a speed V14 and returns to an initial position above the substrate introducing portion 5. As a result, the substrate introducing operation M5 for the first substrate 10 is completed.

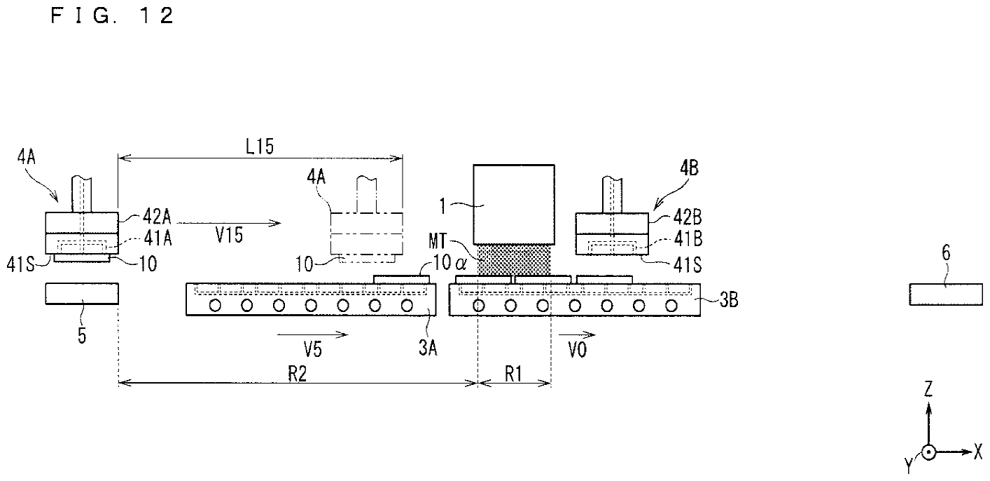

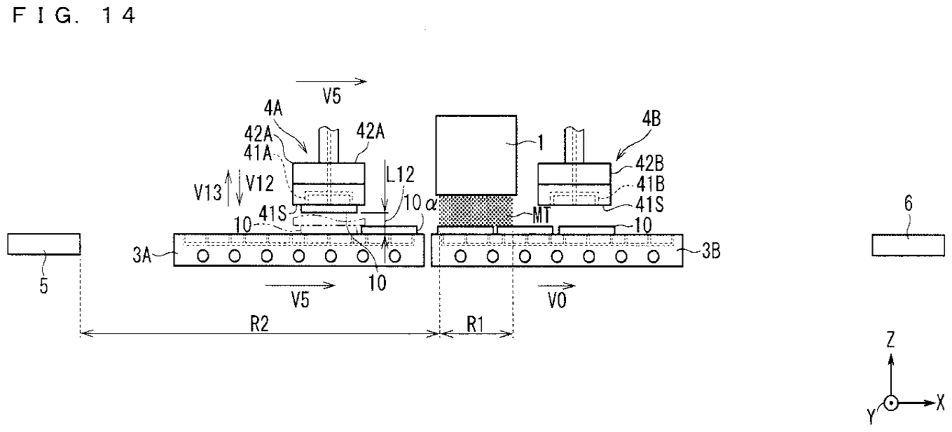

Subsequently, as shown in FIG. 12, the suction gripper 4A grips the substrate 10 before the film deposition treatment from the substrate introducing portion 5, and horizontally moves along the transport direction by a distance L15 at a speed V15 (>V5) while maintaining a difference in height (distance L12 (see FIG. 14)) where the substrate 10 does not interfere with the substrate loading stage 3.

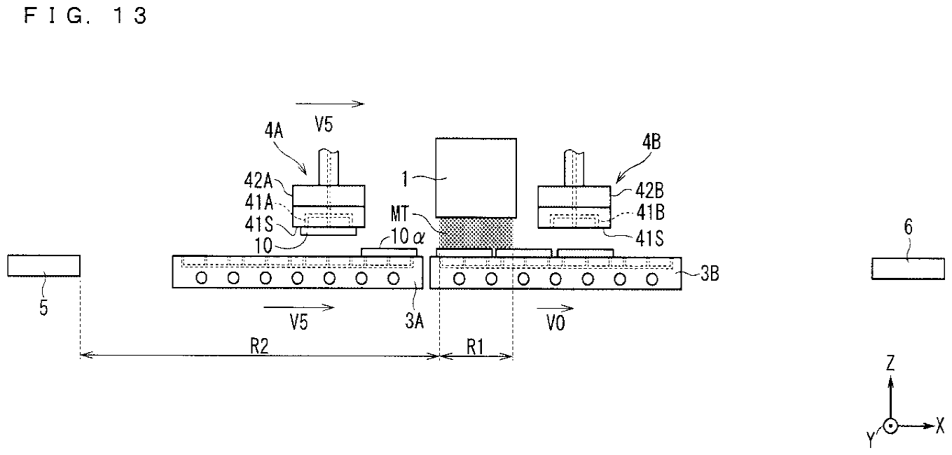

Thereafter, as shown in FIG. 13, when the suction gripper 4A reaches above the adjacent region of a substrate 10α placed on the front end region of the substrate loading stage 3A in the transport direction, the speed is lowered to the speed V5 from the speed V15, and the suction gripper 4A horizontally moves at the same speed as that of the substrate loading stage 3A in the transport direction.

As shown in FIG. 14, the suction gripper 4A performs the lowering operation of the speed V12 together with the horizontal movement of the speed V5 in the transport direction. When the movement distance during release satisfies the above movement distance condition, the lowering operation is stopped, and the substrate releasing treatment is executed. Thereafter, the raising operation is performed at a speed V13, and the distance is returned to a sufficient difference in height (distance L12) where the substrate 10 does not interfere with the substrate loading stage 3A.

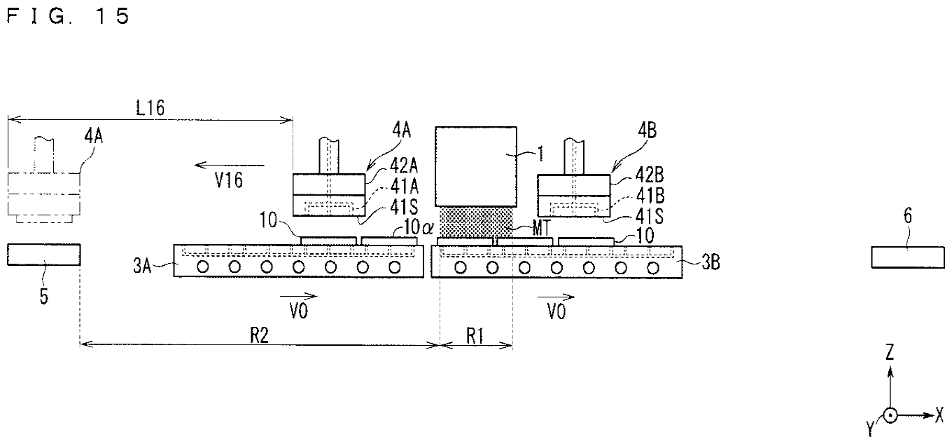

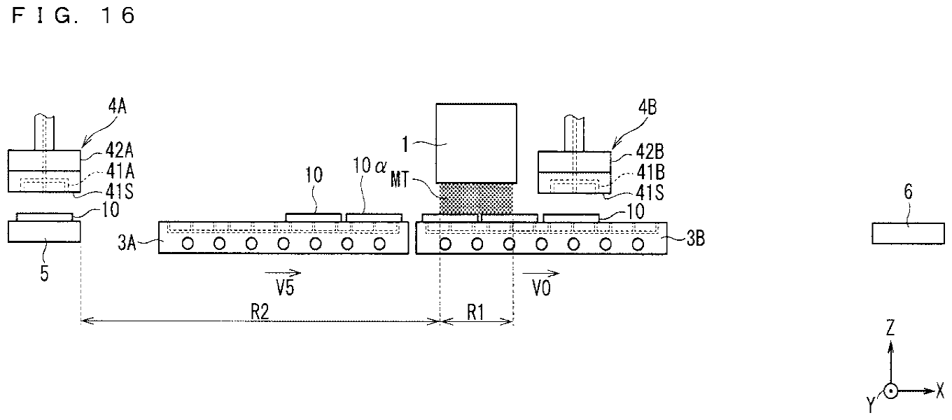

Thereafter, as shown in FIG. 15, the suction gripper 4A horizontally moves in the counter transport direction by a distance L16 at a speed V16, and returns to the initial position above the substrate introducing portion 5 as shown in FIG. 16. As a result, the substrate introducing operation M5 for the second substrate 10 is completed.

Subsequently, the substrate introducing operation M5 shown in FIGS. 8 to 16 is repeatedly executed for the third and subsequent substrates 10, and the substrates 10 to be scheduled are placed in a placing scheduled region on the upper surface of the substrate loading stage 3A.

The substrate introducing operation M5 needs to be executed so that the substrates 10 can be placed on the substrate loading stage 3A at least before the placing scheduled region on the substrate loading stage 3A reaches the injection region R1.

In the situation shown in FIGS. 8 to 16, the substrate loading stage 3B on which the substrate 10 is present in the injection region R1 is transported at the speed V0 along the transport direction, and the substrate loading stage 3A which has not completed the circulating transporting treatment is horizontally moved at the speed V5 in the transport direction.

As shown in FIG. 16, when the substrate loading stage 3A is arranged at a minimum interval behind the substrate loading stage 3B, the circulating transporting treatment for the substrate loading stage 3A is completed.

Thus, the circulating transporting treatment is executed by the combinations of the movement in the +X direction (horizontal movement in the transport direction) at the speed V1, the movement in the −Z direction (lowering movement) at the speed V2, the movement in the −X direction (horizontal movement in the counter transport direction) at the speed V3, the movement in the +Z direction (raising movement) at the speed V4, and the movement in the +X direction (horizontal movement in the transport direction) at the speed V5. The circulating transporting treatment is completed until all the plurality of substrates 10 on the upper surface of the substrate loading stage 3B (the other substrate placing portion) pass through the injection region R1.

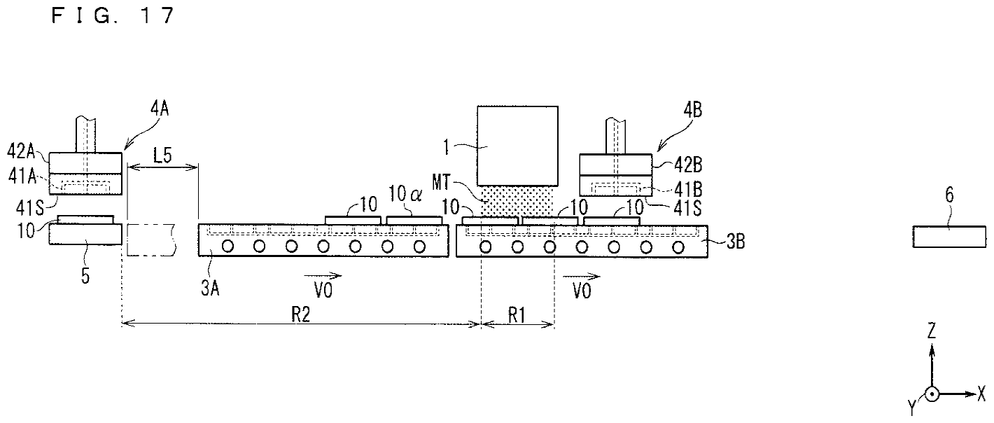

Thereafter, as shown in FIG. 17, in the substrate loading stage 3A for which the circulating transporting treatment is completed, the transferring mechanism 8R lowers the transport speed provided by the traverse movement from the speed V5 to the speed V0.

As a result, the substrate loading stage 3A is transported along the transport direction at the speed V0 (moving speed during film deposition). Thereafter, when it is necessary to further place the substrate 10 on the substrate loading stage 3A, by the substrate introducing operation M5 provided by the suction gripper 4A, the substrate 10 before the film deposition treatment is appropriately arranged on the upper surface of the substrate loading stage 3A (present in the film depositing preparation region R2).

On the other hand, the substrate loading stage 3B which is partially present in the injection region R1 is transported along the transport direction at the speed V0.

Thereafter, after all the substrates 10 on the upper surface of the substrate loading stage 3B have passed through the injection region R1, the circulating transporting treatment is executed for the substrate loading stage 3B as with the substrate loading stage 3A shown in FIGS. 4 to 16. At this time, the substrate loading stage 3A is transported at the speed V0 along the transport direction.

Thus, while the two substrate loading stages 3A and 3B are sequentially circulated by the substrate transferring mechanism 8 including the transferring mechanisms 8L and 8R, the transporting operation (including the circulating transporting treatment) for the substrate loading stages 3A and 3B is executed so that the substrate 10 before the film deposition treatment is always present in the injection region R1.

The substrate loading stage 3 (substrate placing portion) in the film deposition apparatus of the present embodiment includes the heating mechanism 32 (main heating mechanism) heating the substrate at a main heating temperature, so that the placed substrate 10 can be heated. In addition, both the suction grippers 4A and 4B (first and second grippers) include the heating mechanisms 42A and 42B (first and second preheating mechanisms) for heating the gripped substrate 10 at first and second preheating temperatures in a state where the substrate 10 is gripped, which make it possible to heat the substrate 10 in a state where it is gripped even during the substrate introducing operation M5 and the substrate retrieving operation M6.

For example, when the heating treatment is achieved by the first preheating temperature and the main heating temperature, the temperature of the substrate 10 can be raised with a relatively gentle temperature change. When the heating treatment is achieved at the main heating temperature and the second preheating temperature, the temperature of the substrate 10 can be lowered with a relatively gentle temperature change. As a result, the temperature gradient occurring in the substrate 10 can be effectively suppressed, which can effectively avoid a phenomenon in which the substrate 10 is warped and worstly cracked.

As a result, it is possible to execute the heating treatment (healing treatment at the first and second preheating temperatures and the main heating temperature) for the substrate 10 over a long period of time, so that the necessity of rapidly performing the heating treatment is eliminated. This makes it possible to perform the heating treatment in a short period of time, to suppress the temperature gradient occurring in the substrate 10, thereby effectively suppressing the occurrence of warpage or cracking in the substrate 10.

Regarding the suppression of the temperature gradient occurring in the substrate 10, in the main additional constituent part of the film deposition apparatus of the present embodiment, the heating mechanism 42A or the heating mechanism 42B is merely added in at least one of the suction grippers 4A and 4B originally required for the substrate introducing operation M5 and the substrate retrieving operation M6, so that the cost of the apparatus can be minimized.

In the present embodiment, the heating mechanisms 42A and 42B are provided in the suction grippers 4A and 4B. However, a modified configuration is also possible, in which the heating mechanism 42A or the heating mechanism 42B is provided only in one of the suction grippers 4A and 4B. In the case of the modified configuration, the substrate loading stage 3 can heat the substrate 10) at the main heating temperature, and also heat the substrate 10 during one of the substrate introducing operation M5 and the substrate retrieving operation M6, so that the heating treatment can be performed over a long period of time as compared with the case where the heating treatment is performed only by the substrate loading stage 3. This makes it possible to suppress the temperature gradient occurring in the substrate 10 low, to exhibit an effect of suppressing the occurrence of warpage or cracking in the substrate 10. The heating mechanism 42A or the heating mechanism 42B can be omitted in the modified configuration, which can provide further reduced cost of the apparatus.

The first preheating temperature provided by the heating mechanism 42A of the suction gripper 4A is set to about 180° C., and the second heating temperature provided by the suction gripper 4B is set to about 240° C., so that the substrate introducing operation M5 and the substrate retrieving operation M6 can be executed without lowering the temperature of the substrate 10 to a temperature below the initial temperature (normal temperature: around the outside temperature) of the substrate 10 placed on the substrate introducing portion 5, and without raising the temperature of the substrate 10 to a temperature equal to or higher than the main heating temperature (about 400° C.).

Furthermore, the first and second preheating temperatures are set to be lower than the main heating temperature (400° C.), and the first preheating temperature (180° C.) provided by the heating mechanism 42A of the suction gripper 4A and the second preheating temperature (240° C.>180° C.) provided by the heating mechanism 42B of the suction gripper 4B are set to be different temperatures, so that the first preheating temperature, the main heating temperature, and the second preheating temperature can be set to a temperature suitable for depositing a thin film on the substrate 10.

In the present embodiment, as shown in FIG. 18, the gripping surfaces 41S of the suction mechanisms 41A and 41B of the suction grippers 4A and 4B cover (in plan view, completely overlap with) the entire upper surface of the substrate 10, and is formed so as to be wider than the upper surface of the substrate 10.

Therefore, the heating treatment at the first and second preheating temperatures in the gripping state of the substrate 10 on the gripping surface 41S provided by the suction grippers 4A and 4B (first and second grippers) can be performed with good heat retaining property.

In order to achieve the heat retaining effect, at least the gripping surface 41S is desirably formed in such a shape that the maximum dimension of the upper surface of the substrate protruding from the gripping surface 41S is 10 mm or less in the gripping state of the substrate 10.

The substrate loading stage 3 (substrate placing portion) in the film deposition apparatus of the present embodiment further includes the suction mechanism 31, so that the heating treatment at the main heating temperature can be performed in a state where the lower surface of the substrate 10 is suctioned. In addition, the suction grippers 4A and 4B (first and second grippers) further include the suction mechanisms 41A and 41B which cause the gripping surface 41S to suction the upper surface of the substrate 10 to grip the substrate 10, which makes it possible to perform the heating treatment at the first and second preheating temperatures in a state where the substrate 10 is suctioned.

As a result, even if a slight temperature gradient occurs in the substrate 10 during the heating treatment at the first and second preheating temperatures and the main heating temperature, the occurrence of warpage can be effectively suppressed.

The suction gripper 4A blows releasing gas from the suction mechanism 41A onto the upper surface of the substrate 10 to perform the substrate releasing treatment for releasing the substrate 10 from the state where the substrate 10 is gripped during the execution of the substrate introducing operation M5. In this case, the gas temperature of the releasing gas is desirably set to be equal to or higher than the first preheating temperature and equal to or lower than the main heating temperature.

The gas temperature of the releasing gas is set as described above, so that the execution of the substrate releasing treatment provided by the suction gripper 4A does not cause the temperature of the substrate 10 to be lowered to the temperature equal to or lower than the first preheating temperature, and does not cause the temperature of the substrate 10 to be raised to the temperature equal to or higher than the main heating temperature. Therefore, the present embodiment can reliably prevent the cracking of the substrate 10 caused by rapid cooling by the releasing gas, which makes it possible to execute the substrate releasing treatment without adversely affecting the film deposition treatment.

As shown in FIG. 10, the movement distance during release when the substrate releasing treatment for the substrate 10 is performed by the suction gripper 4A satisfies the movement distance condition (more than 0 mm and 10 mm or less).

When the distance L12 satisfies the movement distance condition, the substrate 10 can be placed on the substrate loading stage 3 without causing a position gap by the substrate introducing operation M5 of the suction gripper 4A.

Similarly, when the movement distance during release during the substrate releasing treatment for the substrate 10 provided by the suction gripper 4B also satisfies the movement distance condition, the substrate 10 can be placed on the substrate retrieving portion 6 without causing a position gap by the substrate retrieving operation M6 of the suction gripper 4B.

The suction gripper 4B (second gripper) desirably satisfies a first material condition where the material of the gripping surface 41S gripping the upper surface of the substrate 10 is the same as that of the thin film deposited on the substrate 10. For example, when an aluminum oxide thin film is deposited, the material of the gripping surface 41S is desirably aluminum oxide.

The gripping surface 41S of the suction gripper 4B satisfies the first material condition, so that the occurrence of contamination in which foreign substances are mixed in the thin film formed on the substrate 10 during the execution of the substrate retrieving operation M6 provided by the suction gripper 4B can be effectively suppressed.

The suction grippers 4A and 4B desirably satisfy a second material condition where the material of the gripping surface 41S is a non-metallic material having a heat resistant temperature equal to or higher than the first and second preheating temperatures (first and second non-metallic materials).

The suction grippers 4A and 4B satisfy the second material condition, so that the substrate introducing operation M5 and the substrate retrieving operation M6 can be executed without hindrance in the gripping surface 41S during the heating treatment at the first and second preheating temperatures.

A silicon substrate can be considered as the substrate 10. In this case, the film deposition apparatus of the present embodiment performs the heating treatment for the silicon substrate in a relatively long period of time during the film deposition treatment, and performs the heating treatment in a state where the silicon substrate is suctioned, so that the occurrence of warpage or cracking in the silicon substrate can be effectively suppressed.

In the present embodiment, the thin film forming nozzle 1 (mist injecting portion) is used as a film deposition treatment executing portion, and the film deposition treatment region is the injection region R1.

Therefore, the film deposition apparatus of the embodiment performs the heating treatment for the substrate 10 in a relatively long period of time during the film deposition treatment provided by injecting the raw material mist MT, and performs the heating treatment for the substrate 10 in a state where the substrate 10 is suctioned, so that the occurrence of warpage or cracking in the substrate 10 can be effectively suppressed, and the treatment capability in the film deposition treatment provided by injecting the raw material mist MT can be improved.

The substrate loading stages 3A and 3B (first and second substrate placing portions) in the film deposition apparatus of the present embodiment include the suction mechanism 31 and the heating mechanism 32, respectively. The substrate 10 before the film deposition treatment placed in a preparation period present in the film depositing preparation region R2 is heated until the substrate loading stages 3A and 3B reach the injection region R1 (film deposition treatment region), to eliminate the necessity of rapidly heating the substrate 10. In addition, the heating treatment is executed in a state where the lower surface of the substrate 10 is suctioned by the suction mechanism 31 included in the substrate loading stage 3. As a result, the film deposition apparatus of the present embodiment suppresses the temperature gradient occurring in the substrate 10 during the heating treatment low even if the suction grippers 4A and 4B do not include the heating mechanisms 42A and 42B respectively. Furthermore, the film deposition apparatus heats the substrate 10 in a state where the substrate 10 is suctioned, which makes it possible to exhibit an effect of suppressing the occurrence of warpage or cracking of the substrate 10.

In addition, the substrate transferring mechanism 8 (substrate placing portion transferring device) including the transferring mechanisms 8L and 8R executes the circulating transporting treatment for arranging one substrate loading stage 3 which has passed through the injection region R1 (the substrate loading stage 3A in FIGS. 3 to 16) at circulating speeds V1 to V5 behind the other substrate loading stage 3 (substrate loading stage 3B in FIGS. 3 to 16). As a result, the substrate loading stages 3A and 3B are efficiently moved while the substrate loading stages 3A and 3B are circulated, to allow the placed substrate 10 to sequentially pass through the injection region R1, so that the treatment capability in the film deposition treatment can be improved.

Furthermore, in the present embodiment, the number of substrate loading stages 3 each including the suction mechanism 31 and the heating mechanism 32 is suppressed to the minimum of 2 (substrate loading stages 3A and 3B), which can achieve the substrate transferring mechanism 8 with a relatively simple configuration including the transferring mechanisms 8R and SL for independently moving the substrate loading stages 3A and 3B, respectively. Therefore, the film deposition apparatus of the present embodiment can minimize the cost of the apparatus while suppressing the footprint.

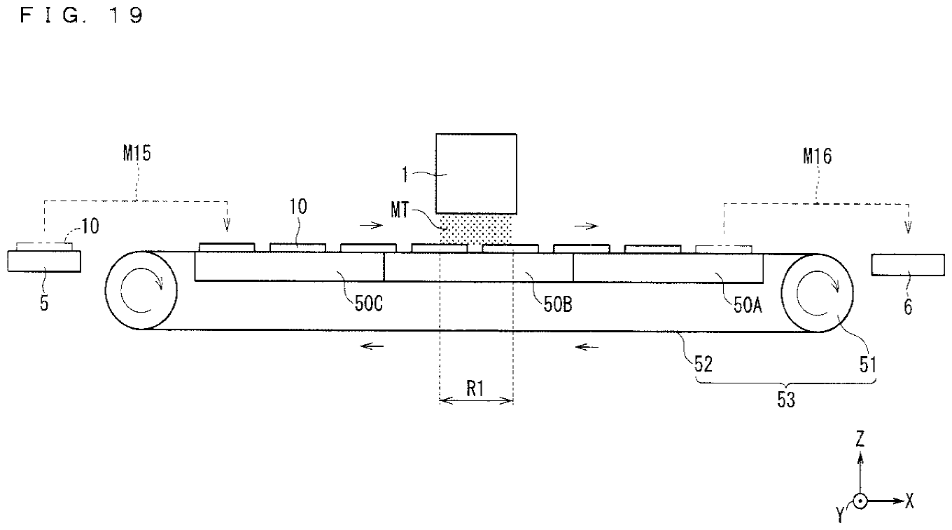

FIG. 19 is an illustration diagram schematically showing a configuration of a conventional film deposition apparatus when a transporting treatment for a plurality of substrates 10 is performed by a conventional conveyer 53.

As shown in FIG. 19, by a conveyor 53 including a roller 51 and a belt 52, a plurality of substrates 10 on the belt 52 are transported along a transport direction (X direction). In the conventional film deposition apparatus, three heating stages 50A to 50C are provided below the belt 52, so that a heating treatment for heating the substrate 10 via the belt 52 is performed.

A raw material mist MT is injected from a thin film forming nozzle 1 in an injection region R1. The substrate 10 on a substrate introducing portion 5 on an upstream side is placed on the belt 52 by a substrate introducing operation M15. The substrate 10 on the belt 52 after passing through the injection region R1 is retrieved onto a substrate retrieving portion 6 on a downstream side by a substrate retrieving operation M16.

In the conventional film deposition apparatus, the conveyor 53 allows the plurality of substrates 10 to sequentially pass through the injection region R1. By providing the three heating stages 50A to 50C, the heating treatment for the substrate 10 can be executed in a relatively long period of time before, during, and after the film deposition treatment.

Thus, in the conventional film deposition apparatus shown in FIG. 19, the substrate 10 is merely placed on the belt 52, so that when a temperature gradient occurs in the substrate 10 during the heating treatment provided by the heating stages 50A to 50C, the substrate 10 is warped.

Furthermore, in order to achieve a long-term heating treatment for the substrate 10, it is necessary to provide three relatively large heating stages 50A to 50C, which causes increased cost of the apparatus.

Thus, the film deposition apparatus of the present embodiment can exhibit high treatment capability without causing warpage or cracking in the substrate 10 to be film-deposited while minimizing the cost of the apparatus, which exhibits an effect unattainable in the conventional film deposition apparatus.

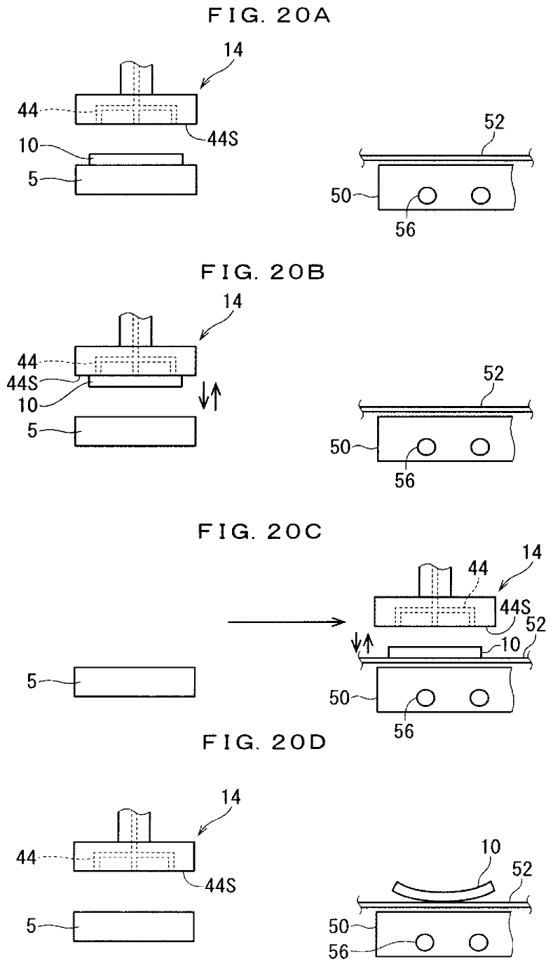

FIG. 20 is an illustration diagram showing the conventional substrate introducing operation M15 in the conventional film deposition apparatus shown in FIG. 19. In FIG. 20, the heating stages 50A to 50C are collectively referred to as a heating stage 50 including a heating mechanism 56.

Hereinafter, with reference to FIG. 20, the substrate introducing operation M15 provided by a conventional suction gripper 14 will be described in detail.

First, as shown in FIGS. 20(a) and 20(b), the suction gripper 14 approaches above the substrate 10 placed on the substrate introducing portion 5. A suction mechanism 44 then causes a gripping surface 44S to suction the upper surface of the substrate 10 so as to grip the substrate 10. In the state where the substrate 10 is gripped, the suction gripper 14 is moved to above the substrate unloaded region on the upper surface of the belt 52.

As shown in FIG. 20(c), a substrate releasing treatment for releasing the gripping state of the substrate 10 on the gripping surface 44S provided by the suction mechanism 44 of the suction gripper 14 is executed in the above state, and the substrate 10 is arranged on the substrate unloaded region on the belt 52. The above operation is the substrate introducing operation M15.

After the substrate introducing operation M15 is executed, the suction gripper 14 moves to above the substrate introducing portion 5, as shown in FIG. 20(d). Thus, when the suction gripper 14 does not include the heating mechanism, the suction gripper 14 cannot execute the heating treatment for the substrate 10 during the execution of the substrate introducing operation M15.

Similarly, even when the conventional suction gripper 14 which does not include the heating mechanism performs the substrate retrieving operation M16, the heating treatment for the substrate 10 cannot be executed during the execution of the substrate retrieving operation M16.

Thus, when the suction gripper 14 which does not include the heating mechanism executes the substrate introducing operation M15 and the substrate retrieving operation M16, the heating treatment for the substrate 10 is executed only in a period of time for which the substrate 10 is placed on the belt 52 above the heating stage 50.

Therefore, as shown in FIG. 20(d), the heating treatment for the substrate 10 is first executed by the heating mechanism 56 of the heating stage 50, so that the heating treatment for the substrate 10 is inevitably performed in a short period of time. As a result, a relatively high temperature gradient occurs in the substrate 10, which causes a high probability that warpage or cracking occurs in the substrate 10.

On the other hand, also in the conventional film deposition apparatus as shown in FIG. 19, the substrate introducing operation M5 and the substrate retrieving operation M6 provided by the suction grippers 4A and 4B including the heating mechanisms 42A and 42B are executed in place of the substrate introducing operation M15 and the substrate retrieving operation M16, which makes it possible to execute the heating treatment for the substrate (heating treatment provided by the heating mechanisms 42A and 42B and the heating mechanism 56) over a relatively long period of time.

As a result, the necessity of rapidly performing the heating treatment is reduced, so that, by employing the suction grippers 4A and 4B for executing the substrate introducing operation M5 and the substrate retrieving operation M6 even in the conventional film deposition apparatus, the temperature gradient occurring in the substrate 10 can be suppressed low, which allows an effect of suppressing the occurrence of warpage or cracking in the substrate 10 to be expected.

However, in order to reduce the cost of the apparatus, improve the treatment capability, and reliably eliminate the problem of occurrence of warpage or cracking in the substrate 10 by performing the heating treatment in a state where the substrate 10 is always suctioned, the transport mechanism of the present embodiment including the substrate transferring mechanism 8 (SL, 8R) and the substrate loading stages 3A and 3B is desirably used.

By setting the circulating speeds V1 to V5 to be higher than the moving speed during film deposition V0 in the film deposition apparatus of the embodiment, one substrate loading stage 3 can be promptly arranged behind the other substrate loading stage 3 by the circulating transporting treatment. The above effect can be achieved by setting at least the average value of the whole of the circulating speeds V1 to V5 to be higher than the moving speed during film deposition V0.

Hereinafter, the speed V0 and the circulating speeds V1 to V5 will be described in detail. Here, distances L0 to L5 related to the speeds V0 to V5 will be described.

As shown in FIG. 4, a distance obtained by subtracting the length of the injection region R1 from a formation length SL3 of the substrate loading stage 3 in the transport direction (X direction) is defined as a distance L0, and a horizontal distance before and after the substrate loading stage 3A performs the horizontal movement operation at the speed V1 in the transport direction is defined as a distance L1.

As shown in FIG. 5, a difference in height before and after the substrate loading stage 3A performs a lowering operation at the speed V2 is defined as a distance L2. Furthermore, as shown in FIG. 6, a horizontal distance before and after the substrate loading stage 3A performs the horizontal movement operation at the speed V3 in the counter transport direction is defined as a distance L3.

Furthermore, as shown in FIG. 7, a difference in height before and after the substrate loading stage 3A performs the raising operation at the speed V4 is defined as a distance L4. As shown in FIG. 17, a horizontal distance before and after the substrate loading stage 3A performs the horizontal movement operation at the speed V5 is defined as a distance L5.

Therefore, in the operation example of the film deposition apparatus of the embodiment shown in FIGS. 3 to 17, it is necessary to satisfy the following expression (1) in order to complete the circulating transporting treatment for the substrate loading stage 3A (one of the substrate placing portions) until all the substrates 10 placed on the substrate loading stage 3B (the other substrate placing portion) pass through the injection region R1 which is the film deposition treatment region.

L0/V0≥L1/V1+L2/V2+L3/V3+L4/V4+L5/V5 (1)

In this case, the distance L0 is determined by the formation length SL3 in the transport direction of the substrate loading stage 3 when the injection region R1 is predetermined. The number of the substrates 10 to be placed on the upper surface (the number of substrates to be placed) is determined by the formation length SL3 of the substrate loading stage 3.

When the distances L1 to L5 and the speeds V0 to V5 are previously set in consideration of the film deposition treatment time and the scale of the film deposition apparatus or the like, the maximum number of the substrates 10 which can be placed on the upper surface of the substrate loading stage 3 having the minimum formation length SL3 satisfying the expression (1) is the optimum number of the substrates to be placed.

For example, provided that the minimum formation length SL3 along the X direction which satisfies the expression (1) is 800 mm when a rectangular substrate 10 having a side of 156 mm is used, five substrates 10 can be placed on along the X direction on the substrate loading stage 3 having the formation length SL3 of 800 mm in the X direction, so that the optimum number of the substrates to be placed is 10 (5×2) when two substrates 10 can be placed along the Y direction as shown in FIG. 2.

Thus, on each of the substrate loading stages 3A and 3B (first and second substrate placing portions) of the film deposition apparatus of the present embodiment, the substrates 10 of the optimum number (predetermined number) are loaded. That is, the optimum number of the substrates to be placed is set so that the circulating transporting treatment of one substrate placing portion (substrate loading stage 3A in FIGS. 3 to 17) is completed until all the substrates 10 on the other substrate placing portion (the substrate loading stage 3B in FIGS. 3 to 17) pass through the injection region R1 which is the film deposition treatment region.

In the embodiment, by arranging the substrates 10 of the optimum number on the upper surface of each of the substrate loading stages 3A and 3B, the transporting operation allows the substrates 10 placed on the upper surfaces of the substrate loading stages 3A and 3B to continuously reach the injection region R1, so that the improvement in the treatment capability in the film deposition treatment can be maximally exhibited.

In the present embodiment, a mist injecting distance D1 (see FIG. 1), which is a distance between the injecting surface 1S in which the mist injection port for injecting the raw material mist from the thin film forming nozzle 1 is formed and the upper surface of the substrate 10, is set to 1 mm or more and 30 mm or less.

Thus, in the film deposition apparatus of the present embodiment, the mist injecting distance D1 of the thin film forming nozzle 1 is set to 1 mm or more and 30 mm or less, which makes it possible to more precisely perform the film deposition treatment provided by injecting the raw material mist MT.

<Other>

In the present embodiment, the two substrate loading stages 3A and 3B are shown as the substrate placing portion. However, the film deposition apparatus using four or more substrate loading stages 3 can also be achieved by improvements such as the provision of two substrate loading stages 3 in each of the transferring mechanisms 8L and SR. However, as in the present embodiment, the achievement of the film deposition apparatus with only the two substrate loading stages 3A and 3B minimizes the number of the substrate loading stages 3, and is excellent in terms of the cost of the apparatus such as the simplification of the structure of the substrate transferring mechanism 8 which is the substrate placing portion transferring device, or the ease of the control contents of the circulating transporting treatment.

The main constituent parts for the effect of being capable of effectively suppressing the occurrence of warpage or cracking in the substrate 10 caused by the film deposition apparatus of the present embodiment are the suction grippers 4A and 4B including the heating mechanisms 42A and 421, and the substrate loading stage 3 including the heating mechanism 32. Therefore, when the substrate transferring mechanism 8 executes the transporting operation for moving at least one substrate loading stage 3 to cause the substrate loading stage 3 to pass through the injection region R1, the above effect can be achieved.

However, in order to improve the treatment capability in the film deposition treatment while suppressing the cost of the apparatus, the configuration of the present embodiment is desirable, in which the substrate transferring mechanism 8 (8L, 8R) executes the transporting operation including the circulating transporting treatment for the two substrate loading stages 3A and 3B.

While the present invention has been described in detail, the foregoing description is in all aspects illustrative, and the present invention is not limited thereto. It is understood that numerous modifications not illustrated can be devised without departing from the scope of the present invention.

### EXPLANATION OF REFERENCE SIGNS

1: thin film forming nozzle
3, 3A, 3B: substrate loading stage
4A, 4B: suction gripper
5: substrate introducing portion
6: substrate retrieving portion
8: substrate transferring mechanism
10: substrate
31: suction mechanism
32: heating mechanism
41A, 41B: suction mechanism
42A, 42B: heating mechanism

1. A film deposition apparatus comprising:
a substrate placing portion which places a substrate and includes a main heating mechanism for heating the placed substrate at a main heating temperature;
a first gripper which executes a substrate introducing operation for gripping a film deposition substrate placed on a substrate introducing portion, moving the substrate in a state where the substrate is gripped, and placing the substrate on said substrate placing portion;
a film deposition treatment executing portion which executes a film deposition treatment for depositing a thin film for the substrate placed on said substrate placing portion in a film deposition treatment region;
a substrate placing portion transferring device which executes a transporting operation for moving said substrate placing portion to cause the substrate placing portion to pass through said film deposition treatment region; and
a second gripper which executes a substrate retrieving operation for gripping the substrate located on said substrate placing portion and having the thin film deposited by executing said film deposition treatment, moving the substrate in a state where the substrate is gripped, and placing the substrate on a substrate retrieving portion, wherein
at least one of said first and second grippers includes preheating mechanisms for heating the gripped substrate at a preheating temperature in the state where the substrate is gripped.

2. The film deposition apparatus according to claim 1, wherein said preheating temperature is lower than said main heating temperature, and higher than an initial temperature of the substrate placed on said substrate introducing portion.

3. The film deposition apparatus according to claim 2, wherein
said preheating mechanism includes a first preheating mechanism provided in said first gripper for heating the gripped substrate at a first preheating temperature, and a second preheating mechanism provided in said second gripper for heating the gripped substrate at a second preheating temperature,
said preheating temperature includes said first and second preheating temperatures, and
said first preheating temperature and said second preheating temperature are different from each other.

4. The film deposition apparatus according to claim 3, wherein said second preheating temperature is higher than said first preheating temperature.

5. The film deposition apparatus according to claim 4, wherein
each of said first and second grippers has a gripping surface gripping the substrate and having a maximum dimension of 10 mm or less by which the substrate protrudes from the gripping surface in the state where the substrate is gripped.

6. The film deposition apparatus according to claim 5, wherein
said first and second grippers further include suction mechanisms suctioning the substrate according to vacuum suction to grip the substrate, respectively and
said substrate placing portion further includes a suction mechanism suctioning the placed substrate according to vacuum suction.

7. The film deposition apparatus according to claim 6, wherein
said first gripper blows releasing gas to the substrate to perform a substrate releasing treatment for releasing the substrate from the state where the substrate is gripped during execution of said substrate introducing operation, and
a gas temperature of said releasing gas is set to be equal to or higher than said first preheating temperature and equal to or lower than said main heating temperature.

8. The film deposition apparatus according to claim 7, wherein said first gripper has a movement distance during release of more than 0 mm and 10 mm or less, the movement distance during release being a distance between an upper surface of said substrate placing portion and a lower surface of the substrate in the state where the substrate is gripped immediately before execution of said substrate releasing treatment.

9. The film deposition apparatus according to claim 3, wherein a material of the gripping surface for gripping the substrate in said second gripper is the same as that of said thin film.

10. The film deposition apparatus according to claim 3, wherein materials of the gripping surfaces for gripping the substrate in said first and second grippers are first and second nonmetal materials having a heatproof temperature equal to or higher than said first and second preheating temperatures.

11. The film deposition apparatus according to claim 3, wherein the substrate placed on said substrate placing portion is a silicon substrate.

12. The film deposition apparatus according to claim 3, wherein
said film deposition treatment executing portion includes a mist injecting portion which injects a raw material mist obtained by misting a raw material solution into the air to execute said film deposition treatment, and
said film deposition treatment region is an injection region of said raw material mist.
